(19) United States
(12) Patent Application Publication
(10) Pub. No.: US 2008/0190560 A1
(43) Pub. Date: Aug. 14, 2008

(54) Microwave Plasma Processing Apparatus

(76) Inventors: Caizhong Tian, Hyogo-Ken (JP); Kiyotaka Ishibashi, Hyogo-ken (JP); Toshihisa Nozawa, Hyogo-ken (JP); Nobuhiko Yamamoto, Hyogo-ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/885,625

(22) PCT Filed: Feb. 21, 2006
(86) PCT No.: PCT/JP06/03048

§ 371 Date: Sep. 4, 2007

(30) Foreign Application Priority Data
Mar. 4, 2005 (JP) 2005-060151

(51) Int. Cl. H01L 21/3065; C23C 16/453

(52) U.S. Cl. 156/345.42; 118/723 ME

(57) ABSTRACT

The present invention is a microwave plasma processing apparatus comprising: a chamber in which an object to be processed is housed; a process gas supply unit that supplies a process gas into the chamber; a microwave generating source that generates a microwave for forming a plasma due to the process gas in the chamber; a waveguide unit that guides the microwave generated by the microwave generating source toward the chamber; a planar antenna made of a conductive material provided with a plurality of microwave radiating holes for radiating the microwave guided by the waveguide unit toward the chamber; a microwave transmitting plate made of a dielectric material, the microwave transmitting plate serving as a top wall of the chamber and transmitting the microwave that has passed through the microwave radiating holes of the planar antenna; and a slow-wave plate disposed on an opposite side of the planar antenna relative to the microwave transmitting plate, the slow-wave plate having a function of shortening a wavelength of the microwave that reaches the planar antenna. The planar antenna and the microwave transmitting plate are in contact with each other, with substantially no air therebetween, the slow-wave plate and the microwave transmitting plate are made of the same material, and an equivalent circuit formed by the slow-wave plate, the planar antenna, the microwave transmitting plate, and the plasma due to the process gas formed in the chamber satisfies a resonance condition.

### FIELD OF THE INVENTION

The present invention relates to a microwave plasma processing apparatus that processes an object to be processed with a microwave plasma.

### BACKGROUND ART

A plasma process is an indispensable technique for manufacturing a semiconductor device. With an ongoing need for higher integration and higher speed of an LSI, a design rule of a semiconductor device constituting an LSI has been more and more miniaturized. At the same time, the size of a semiconductor wafer has been enlarged. In accordance therewith, there has been required a plasma processing apparatus suitable for the miniaturized design rule and the enlarged semiconductor wafer.

However, a prevalently employed conventional plasma processing apparatus of a parallel-plate type or an inductive-coupling type is likely to cause a plasma damage to a fine device, because a high electron temperature is used. In addition, since an area of a higher plasma density is limited, it is difficult to uniformly, promptly plasma-process a large semiconductor wafer.

Thus, an RLSA (Radial Line Slot Antenna) microwave plasma processing apparatus, which is capable of uniformly forming a plasma of a high density and a low electron temperature, has been widely regarded (for example, JP2000-294550A).

The RLSA microwave plasma processing apparatus has a planar antenna (Radial Line Slot Antenna) which is disposed above a chamber. In the planar antenna, a number of slots are formed with a predetermined pattern. A microwave guided from a microwave generating source is radiated toward the chamber through the slots in the planar antenna. The microwave is radiated into the chamber, which is held in a vacuum state, through a microwave transmitting plate made of a dielectric material disposed below the planar antenna. Due to the microwave electric field, a gas introduced into the chamber is made plasma. An object to be processed, such as a semiconductor wafer, is plasma-processed by the thus generated plasma.

The RLSA microwave plasma processing apparatus can achieve a high plasma density over a wide area directly below the antenna, so that a uniform plasma process can be realized in a short period of time. Further, a plasma of a low electron temperature can be formed, the device is less damaged.

In the RLSA microwave plasma processing apparatus, there has been known a technique of providing an air gap between the planar antenna and the microwave transmitting plate, for adjusting a microwave electric field distribution in the microwave transmitting plate so as to stabilize a plasma mode (Jpn. Appl. Phys. Vol. 38 (1999) pp. 2082-2088 Part 1, No. 4A, April 1999).

However, since an impedance of the air gap is higher than that of the dielectric material forming the microwave transmitting plate, provision of the air gap between the planar antenna and the microwave transmitting plate may increase microwave power loss in the air gap. As a result, microwave power efficiency may be degraded or abnormal electric discharge may be easily generated inside the antenna.

### SUMMARY OF THE INVENTION

The present invention has been made in view of the above circumstances. The object of the present invention is to provide a microwave plasma processing apparatus wherein microwave power loss is small, microwave power efficiency is not reduced, and abnormal electric discharge is unlikely to occur inside an antenna.

In order to achieve the above object, the present invention is a microwave plasma processing apparatus comprising: a chamber in which an object to be processed is housed; a process gas supply unit that supplies a process gas into the chamber; a microwave generating source that generates a microwave for forming a plasma due to the process gas in the chamber; a waveguide unit that guides the microwave generated by the microwave generating source toward the chamber; a planar antenna made of a conductive material provided with a plurality of microwave radiating holes for radiating the microwave guided by the waveguide unit toward the chamber; a microwave transmitting plate made of a dielectric material, the microwave transmitting plate serving as a top wall of the chamber and transmitting the microwave that has passed through the microwave radiating holes of the planar antenna; and a slow-wave plate disposed on an opposite side of the planar antenna relative to the microwave transmitting plate, the slow-wave plate having a function of shortening a wavelength of the microwave that reaches the planar antenna; wherein the planar antenna and the microwave transmitting plate are in contact with each other, with substantially no air therebetween, the slow-wave plate and the microwave transmitting plate are made of the same material, and an equivalent circuit formed by the slow-wave plate, the planar antenna, the microwave transmitting plate, and the plasma due to the process gas formed in the chamber satisfies a resonance condition.

According to the present invention, since the planar antenna and the microwave transmitting plate are in contact with each other so as to eliminate an air gap which has been conventionally formed, there is no possibility that microwave power loss is caused by such an air gap. Thus, lowering of microwave power efficiency and/or occurrence of abnormal electric discharge inside the antenna can be restrained.

The mere elimination of an air gap may increase reflection of the microwave to impair stability of the plasma. However, according to the present invention, since the equivalent circuit formed by the slow-wave plate, the planar antenna, the microwave transmitting plate, and the plasma can resonate, reflection of the microwave can be made minimized. Moreover, since the slow-wave plate and the microwave transmitting plate are made of the same material, interface reflection of the microwave can be prevented, so that the plasma can be stably maintained.

In addition, the present invention is a microwave plasma processing apparatus comprising: a chamber in which an object to be processed is housed; a process gas supply unit that supplies a process gas into the chamber; a microwave generating source that generates a microwave for forming a plasma due to the process gas in the chamber; a waveguide unit that guides the microwave generated by the microwave generating source toward the chamber; a planar antenna made of a conductive material provided with a plurality of microwave radiating holes for radiating the microwave guided by the waveguide unit toward the chamber; a microwave transmitting plate made of a dielectric material, the microwave transmitting plate serving as a top wall of the chamber and transmitting the microwave that has passed through the microwave radiating holes of the planar antenna; and a slow-wave plate disposed on an opposite side of the planar antenna relative to the microwave transmitting plate, the slow-wave plate having a function of shortening a wavelength of the microwave that reaches the planar antenna; wherein the planar antenna and the microwave transmitting plate are in contact with each other, with substantially no air therebetween, the slow-wave plate and the microwave transmitting plate are made of materials with a ratio between dielectric constants of these materials being within a range between 70% and 130%, and an equivalent circuit formed by the slow-wave plate, the planar antenna, the microwave transmitting plate, and the plasma due to the process gas formed in the chamber satisfies a resonance condition.

According to the present invention, since the planar antenna and the microwave transmitting plate are in contact with each other so as to eliminate an air gap which has been conventionally formed, there is no possibility that microwave power loss is caused by such an air gap. Thus, lowering of microwave power efficiency and/or occurrence of abnormal electric discharge inside the antenna can be restrained.

The mere elimination of an air gap may increase reflection of the microwave to impair stability of the plasma. However, according to the present invention, since the equivalent circuit formed by the slow-wave plate, the planar antenna, the microwave transmitting plate, and the plasma can resonate, reflection of the microwave can be made minimized. Moreover, since the slow-wave plate and the microwave transmitting plate are made of materials with a ratio between dielectric constants of these materials being within a range between 70% and 130%, interface reflection of the microwave can be prevented, so that the plasma can be stably maintained.

In either of the above-described inventions, a thickness of the microwave transmitting plate is within a range between ½ and ¼ of the wavelength of the microwave to be introduced into the microwave transmitting plate, and a microwave reflection ratio of the planar antenna is within a range between 0.4 and 0.8. With these conditions, the equivalent circuit can satisfy the resonance condition.

As the waveguide unit, there can be employed a waveguide unit including a rectangular waveguide that propagates the microwave generated from the microwave generating source in a TE mode, a mode converter that converts the TE mode to a TEM mode, and a coaxial waveguide that propagates the microwave converted to the TEM mode toward the planar antenna.

In addition, it is preferable that each of the microwave radiating holes formed in the planar antenna has an elongated groove shape, every adjacent two of the microwave radiating holes are arranged in directions crossing each other so as to form one microwave radiating hole pair, and the plurality of microwave radiating hole pairs are concentrically arranged.

In addition, there can be further provided a cover member that covers the slow-wave plate and the planar antenna. In this case, it is preferable that the cover member is provided with a cooling medium passage, and the slow-wave plate, the planar antenna, and the microwave transmitting plate are cooled by allowing a cooling medium to flow through the cooling medium passage. Since there is no air gap in this structure, it is possible to sufficiently cool the microwave transmitting plate, as compared with a conventional microwave transmitting plate which could not be efficiently cooled because of the presence of an air gap of a lower thermal conductivity.

For example, a frequency of the microwave is 2.45 GHz, a relative dielectric constant of the slow-wave plate and the microwave transmitting plate is between 3.5 and 4.5, and the microwave radiating holes are arranged in double circles.

For example, it is preferable that the slow-wave plate and the microwave transmitting plates are made of quartz, and the microwave plasma processing apparatus is a plasma etching apparatus or a plasma surface modifying apparatus.

Alternatively, it is preferable that the slow-wave plate and the microwave transmitting plate are made of alumina, and the microwave plasma processing apparatus is a plasma CVD apparatus.

### BRIEF DESCRIPTION OF THE DRAWINGS

FIG. 1 is a schematic sectional view of a microwave plasma processing apparatus in one embodiment according to the present invention;

FIG. 2 is a plan view of a structure of a planar antenna;

FIG. 3 is a view of an equivalent circuit formed by a slow-wave plate, the planar antenna, a microwave transmitting plate, and a plasma;

FIGS. 4(a) and 4(b) are views for explaining a thickness of the microwave transmitting plate;

FIG. 5 is a view of a simulation result of an electric field distribution on a surface of a plasma transmitting plate in the microwave plasma processing apparatus according to the present invention;

FIG. 6 is a graph of a measuring result of an example of an electron temperature distribution in the microwave plasma processing apparatus according to the present invention;

FIG. 7 is a view of an example of an electron density distribution in the microwave plasma processing apparatus according to the present invention;

FIG. 8(a) is a view of a simulation result of a microwave electric field strength on a surface of the microwave transmitting plate in the microwave plasma processing apparatus according to the present invention; and

FIG. 8(b) is a view of a simulation result of a microwave electric field strength on a surface of the microwave transmitting plate in a conventional microwave plasma processing apparatus.

### BEST MODE FOR CARRYING OUT THE INVENTION

An embodiment of the present invention will be specifically described below, with reference to the attached drawings.

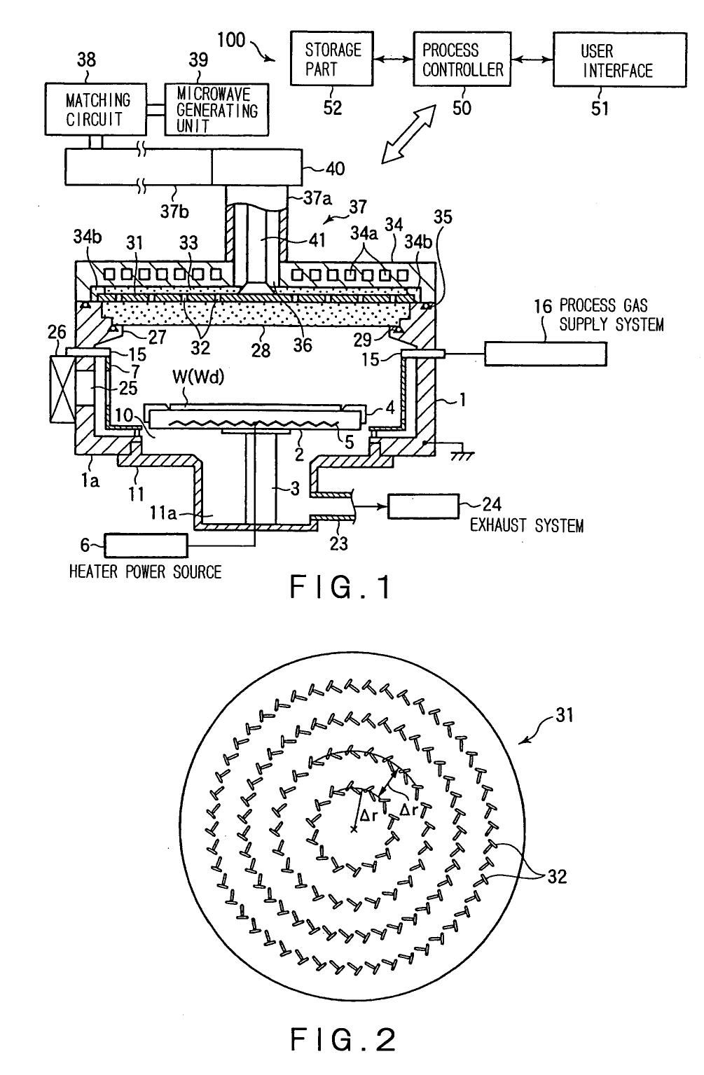

FIG. 1 is a schematic sectional view of a microwave plasma processing apparatus in one embodiment according to the present invention.

The microwave plasma processing apparatus 100 is structured as an RLSA microwave plasma processing apparatus that radiates a microwave guided from a microwave generating source into a chamber so as to form therein a plasma, by using a planar antenna (Radial Line Slot Antenna) in which a number of slots are formed with a predetermined pattern.

The microwave plasma processing apparatus 100 includes a substantially cylindrical chamber 1 which is air-tightly sealed and grounded. A circular opening 10 is formed in a substantially central part of a bottom wall 1a of the chamber 1. On the bottom wall 1a, there is disposed an exhaust hood 11 which is communicated with the opening 10 and extending downward. The chamber 1 includes a susceptor 2 for horizontally supporting a wafer W as a substrate to be processed. The susceptor 2 is made of ceramics such as AlN. The susceptor 2 is supported by a cylindrical support member 3 extending upward from a bottom center of the exhaust hood 11. The support member 3 is also made of ceramics such as AlN. A guide ring 4 for guiding the wafer W is disposed on an outer periphery of the susceptor 2. An electrical resistance heater 5 is embedded in the susceptor 2. With a power fed from a heater power source 6, the heater 5 heats the susceptor 2. The heat of the susceptor 2 heats the wafer W as an object to be processed. A cylindrical liner 7 made of quartz is disposed on an inner circumferential wall of the chamber 1.

The susceptor 2 has wafer support pins (not shown) for supporting and vertically moving the wafer W, such that the pins are projectable and retractable relative to a surface of the susceptor 2.

An annular gas inlet member 15 is disposed on a sidewall of the chamber 1. A process gas supply system 16 is connected to the gas inlet member 15. Thus, a predetermined process gas is introduced into the chamber 1 from the process gas supply system 16 through the gas inlet member 15. The gas inlet member may be arranged like a shower. Gases suitable for various plasma processes are used as process gases. For example, when a tungsten-based gate electrode is subjected to an oxidation process such as a selective oxidation process, an Ar gas, an H₂ gas, an O₂ gas, and so on are used.

An exhaust pipe 23 is connected to a side surface of the exhaust hood 11. An exhaust system 24 including a high-speed vacuum pump is connected to the exhaust pipe 23. When the exhaust system 24 is activated, a gas in the chamber 1 is uniformly discharged into a lower space 11a of the exhaust hood 11, and is then discharged through the exhaust pipe 23. Thus, an inside of the chamber 1 can be promptly depressurized at a predetermined vacuum degree, e.g., 0.133 Pa.

In the sidewall of the chamber 1, there are disposed a loading/unloading port 25 through which the wafer W is transferred between the chamber 1 and a transfer chamber (not shown) adjacent to the plasma processing apparatus 100, and a gate valve 26 for opening and closing the loading/unloading port 25.

An upper part of the chamber 1 provides an opening. A ring-shaped support part 27 is disposed along a circumferential part of the opening. A microwave transmitting plate 28 which transmits a microwave is air-tightly disposed on the support part 27 via a sealing member 29. Thus, the inside of the chamber 1 is hermetically held. The microwave transmitting plate 28 is made of a dielectric material, such as quartz and ceramics such as Al₂O₃.

A discoid planar antenna 31 is disposed above the microwave transmitting plate 28. The planar antenna 31 is opposed to the susceptor 2 via the microwave transmitting plate 28. The planar antenna 31 is engaged with an upper end of the sidewall of the chamber 1. The planar antenna 31 is made of a conductive material, such as a copper or aluminium plate with its surface plated with gold. The planar antenna 31 is provided with a number of microwave radiating holes (slots) 32 formed with a predetermined pattern. Namely, the planar antenna 31 constitutes an RLSA antenna. As shown in FIG. 2, each of the microwave radiating holes 32 has an elongated groove shape, for example. In the example shown in FIG. 2, every two adjacent microwave radiating holes 32 are arranged in directions crossing each other, typically, in directions perpendicular to each other (forming a “T-shape”). These pairs (sets) of microwave radiating holes 32 are concentrically arranged. A length of each microwave radiating hole 32 and a distance between two adjacent pairs (sets) of microwave radiating holes 32 are determined corresponding to the wavelength of a microwave, for example. In FIG. 2, it is preferable that a radial distance Ar between the concentrically arranged two pairs (sets) of microwave radiating holes 32 is identical to the wavelength of a microwave in the below-described slow-wave plate 33, and that a length from the center of the planar antenna 31 to the innermost microwave radiating hole 32 conforms to the distance Ar, in order to radiate a strong electric field from the planar antenna 31. In the example shown in FIG. 2, four turns (quadruple circle) of the microwave radiating holes 32 are arranged. A shape of each microwave radiating hole 32 is optional. That is, the microwave radiating hole 32 may be of a circular shape or an arcuate shape. In addition, an arrangement manner of the (sets of) microwave radiating holes 32 is not particularly limited. For example, in addition to the concentric arrangement, the microwave radiating holes 32 may be arranged helically or radially.

On an upper surface of the planar antenna 31, there is disposed the slow-wave plate 33 which is made of a dielectric material having a dielectric constant larger than vacuum. The slow-wave plate 33 has a function of shortening the wavelength of a microwave in the slow-wave plate, as compared with the wavelength of a microwave in vacuum.

A shield cover member 34 is disposed on the upper surface of the chamber 1 so as to cover the planar antenna 31 and the slow-wave plate 33. The shield cover member 34 is made of a metallic material such as aluminum or stainless steel. The upper surface of the chamber 1 and the shield cover member 34 are sealed with a sealing member 35.

The shield cover member 34 is provided with a cooling water passage 34a. By allowing a cooling water to flow through the cooling water passage 34a, the planar antenna 31, the microwave transmitting plate 28, the slow-wave plate 33, and the shield cover member 34 can be cooled. The shield cover member 34 is grounded.

An opening 36 is formed in a center of the shield cover member 34. A waveguide 37 is connected to the opening 36. A microwave generating unit 39 is connected to an end of the waveguide 37 via a matching circuit 38. Thus, a microwave having a wavelength of, e.g., 2.45 GHz, which has been generated by the microwave generating unit 39, is propagated to the planar antenna member 31 through the waveguide 37. Alternatively, a microwave having a wavelength of 8.35 GHz or 1.98 GHz may be used.

The waveguide 37 has a coaxial waveguide 37a of a circular cross-section, which is extended upward from the opening 36 of the shield cover member 34, and a rectangular waveguide 37b of a rectangular cross-section, which is connected to an upper end of the coaxial waveguide 37a and is extended in a horizontal direction. A mode converter 40 is disposed on an end part of the rectangular waveguide 37b on the connecting side to the coaxial waveguide 37a. An inside conductor 41 is extended through a center of the coaxial waveguide 37a. A lower end of the inside conductor 41 is securely connected to a central part of the planar antenna 31.

The respective constituent members of the plasma processing apparatus 100 are connected to a process controller 50 so as to be controlled by the process controller 50. A user interface 51 and a storage part 52 are connected to the process controller 50. The user interface 51 includes a keyboard through which, for example, a command is inputted by a process manager for managing the respective constituent members of the plasma processing apparatus 100, and a display for visualizing and displaying operating conditions of the respective constituent members of the plasma processing apparatus 100. The storage part 52 stores recipes, in each of which a control program and/or process condition data, for executing various processes performed by the plasma processing apparatus 100 under control of the process controller 50, are recorded.

As the need arises, a given recipe is called from the storage part 52 and is executed by the process controller 50, based on a command from the user interface 51. Thus, under control of the process controller 50, a desired process can be performed by the plasma processing apparatus 100.

Next, the slow-wave plate 33, the planar antenna 31, and the microwave transmitting plate 28 in this embodiment are described in more detail below.

In this embodiment, as shown in FIG. 1, the planar antenna 31 and the microwave transmitting plate 28 are closely in contact with each other, whereby there is no conventional air gap. The slow-wave plate 33 and the planar antenna 31 are also in contact with each other. However, the mere elimination of the air gap increases reflection of the microwave seen from the mode converter 40, which impairs both stability of the plasma and microwave power efficiency.

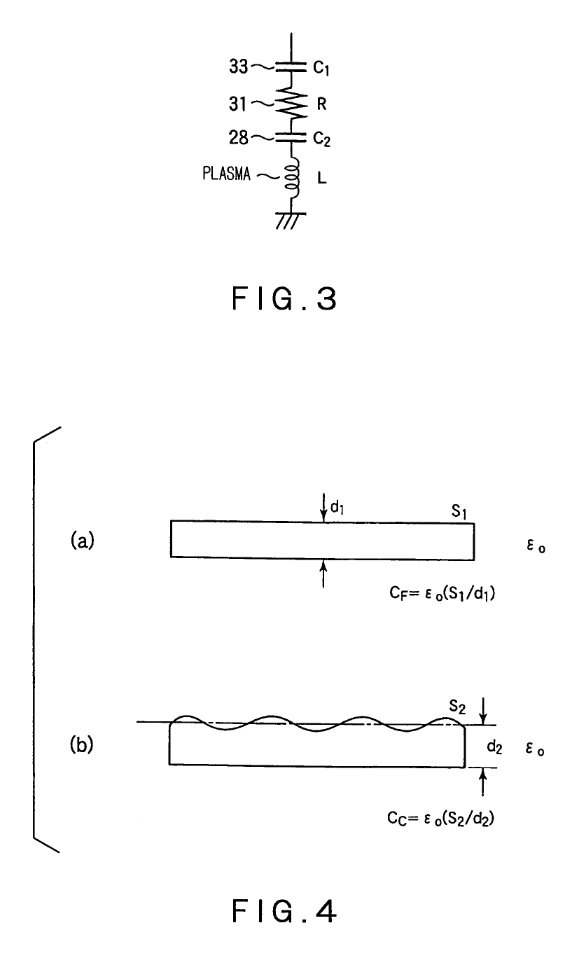

Thus, in this embodiment, an equivalent circuit, as shown in FIG. 3, which is formed by the slow-wave plate 33, the planar antenna 31, the microwave transmitting plate 28, and the plasma, satisfies a resonance condition. In addition, the slow-wave plate 33 and the microwave transmitting plate 28 are made of the same material. Since the equivalent circuit satisfies a resonance condition, reflection of the microwave can be minimized. Meanwhile, since the slow-wave plate 33 and the microwave transmitting plate 28 are made of the same material, interface reflection of the microwave can be prevented. Accordingly, microwave power efficiency can be favorably maintained, while stability of the plasma can be elevated.

As shown in FIG. 3, the slow-wave plate 33 and the plasma transmitting plate 28 serve as condensers, the planar antenna 31 serves as a resistance, and the plasma serves as a coil. As shown in the equivalent circuit of FIG. 3, when a capacitance of the slow-wave plate 33 is represented as C1, a capacitance of the plasma transmitting plate 28 is represented as C2, a resistance of the planar antenna 31 is represented as R, an inductance of the plasma is represented as L, and a frequency of the microwave is represented as f, the following expression (1) has to be satisfied for achieving a resonance state. That is to say,

$$f = \frac{1}{2 π \sqrt{LC}} \qquad ( 1 )$$

in which C=1/{(1/C1)+(1/C2)}.

In order to satisfy the resonance condition, it is effective that a thickness of the microwave transmitting plate 28 defining the capacitance is within a range between ½ and ¼ (½λ and 4/1λ) of a wavelength of the microwave in the microwave transmitting plate 28, and that a microwave reflection ratio (power reflection coefficient) of the planar antenna 31 seen from the mode converter 40 is within a range between 0.4 and 0.8.

Values of the capacitances included in the above expression (1) defining the resonance condition are inversely proportional to thicknesses of the constituent members. As to the slow-wave plate 33, when a thickness thereof is narrower, the planar antenna 31 and the microwave transmitting plate 28 can be efficiently cooled. Thus, a thickness of the microwave transmitting plate 28 (which is the capacitance C2 having a dominant effect on the value of the capacitance C) is defined within a range for realizing the resonance. When the thickness of the microwave transmitting plate 28 is larger than ½ of a wavelength of the microwave introduced into the microwave transmitting plate 28, or is smaller than ⅓ thereof, an area satisfying the resonance condition becomes smaller. When the thickness of the microwave transmitting plate 28 is smaller than ¼ of a wavelength of the microwave, it is difficult to cause a resonance phenomenon.

As shown in FIG. 4(a), when the microwave transmitting plate 28 has a flat shape, an actual thickness d1 thereof is used as the thickness of the microwave transmitting plate 28. In this case, when a capacitance of the microwave transmitting plate 28 is represented as CF, a relative dielectric constant thereof is represented as ε0, and a surface area thereof is represented as S1, the following expression (2) is satisfied.

CF=ε0 (S1/d1) (2)

On the other hand, when the microwave transmitting plate 28 has a complicated shape, a corresponding thickness d2 calculated from an expression for the capacitance is used as the thickness of the microwave transmitting plate 28. Namely, when a capacitance of the microwave transmitting plate 28 of a complicated shape is represented as CC, and a surface area thereof is represented as S2, the following expression (3) is satisfied. The surface area S2 can be unfailingly obtained. Thus, when it is difficult to obtain the thickness d2 because of the complicated shape, the capacitance CC is actually measured, and thereafter the expression (3) is inversely operated to obtain the corresponding thickness d2 to be used as the thickness of the microwave transmitting plate 28.

CC=ε0 (S2/d2) (3)

As shown in FIG. 4(b), the corresponding thickness d2 corresponds to an average thickness of the larger and smaller thicknesses.

When the microwave reflection ratio of the planar antenna 31 is lower than 0.4, it is difficult to adjust the resonance condition. This is because, a phase is largely changed when a frequency is changed. On the other hand, when the microwave reflection ratio of the planar antenna 31 exceeds 0.8, it is essentially difficult to satisfy the resonance condition.

Preferably, the slow-wave plate 33 and the microwave transmitting plate 28 are made of the same material. However, even when the slow-wave plate 33 and the microwave transmitting plate 28 are made of different materials, it has been confirmed by a simulation that the resonance condition can be invariably ensured, provided that a ratio between dielectric constants of these materials is within a range between 70% and 130%.

In the plasma processing apparatus 100 as structured above, the gate valve 26 is opened at first, and a wafer W as an object to be processed is loaded into the chamber 1 via the loading/unloading port 25. Then, the wafer W is placed on the susceptor 2.

Thereafter, a predetermined process gas is introduced into the chamber 1 from the gas supply system 16 through the gas inlet member 15, and the chamber 1 is maintained at a predetermined pressure. For example, when a tungsten-based gate electrode is subjected to an oxidation process such as a selective oxidation process, an Ar gas, an H₂ gas, an O₂ gas, and so on are introduced as the process gases into the chamber 1, and a pressure in the chamber 1 is set at, e.g., 3 to 700 Pa.

Then, a microwave is guided from the microwave generating unit 39 to the waveguide 37 through the matching circuit 38. The microwave is supplied to the planar antenna member 31 through the rectangular waveguide 37b, the mode converter 40, the coaxial waveguide 37a, and the slow-wave plate 33, in this order. From the planar antenna member 31, the microwave passes through the microwave transmitting plate 28, and is radiated to a space above the wafer W in the chamber 1. The microwave is propagated through the rectangular waveguide 37b in a TE mode. The microwave of the TE mode is converted into a microwave of a TEM mode by the mode converter 40. The microwave of the TEM mode is propagated through the coaxial waveguide 37a toward the planar antenna member 31.

Due to the microwave radiated into the chamber 1 from the planar antenna member 31 via the microwave transmitting plate 28, the process gases which have been introduced into the chamber 1 are made plasma. A predetermined process such as the oxidation process is performed by the plasma.

The plasma processing apparatus 100 in this embodiment can realize a plasma having a density as high as about 10¹²/cm³ or more, and an electron temperature as low as about 1.5 eV or less. Thus, the plasma process can be performed at a low temperature for a short period of time. In addition, a plasma damage caused by ions to a base film can be alleviated.

Further, in this embodiment, as shown in FIG. 1, since the planar antenna 31 and the microwave transmitting plate 28 are in contact with each other so as to eliminate an air gap which has been conventionally formed, there is no possibility that microwave power loss is caused by such an air gap. Furthermore, lowering of microwave power efficiency, and abnormal electric discharge, which is likely to occur in a gap between the microwave radiating holes (slots) 32 in the antenna and a part near the slow-wave plate 33, can be prevented.

The mere elimination of an air gap may increase reflection of the microwave seen from the mode converter 40 to deteriorate stability of the plasma. However, according to the present invention, since the equivalent circuit formed by the slow-wave plate 33, the planar antenna 31, the microwave transmitting plate 28, and the plasma can resonate, reflection of the microwave can be made minimized. Moreover, since the slow-wave plate 33 and the microwave transmitting plate 28 are made of the same material, interface reflection of the microwave can be prevented. Therefore, lowering of microwave power efficiency and occurrence of abnormal electric discharge inside the antenna can be prevented as much as possible, while the plasma can be stably maintained. Incidentally, it is sufficient that the planar antenna 31 and the microwave transmitting plate 28 are in contact with each other, with substantially no air therebetween. That is to say, even when there is a clearance not more than 0.1 mm which is caused by contact error or thermal expansion, such a slight clearance can be allowed (within the scope of the present invention).

In addition, no air gap of a low thermal conductivity is present between the planar antenna 31 and the microwave transmitting plate 28. Thus, when a cooling water is allowed to flow through the cooling water passage 34a formed in the shield cover member 34 to cool the planar antenna 31, the microwave transmitting plate 28, the slow-wave plate 33, and the shield cover member 34, the microwave transmitting plate 28 can be efficiently cooled, although the microwave transmitting plate 28 has been conventionally incapable of being efficiently cooled.

Next, the experiment conducted for confirming the effect of the present invention is described below.

In this experiment, the following slow-wave plate 33, the planar antenna 31, and the plasma transmitting plate 28 were used.

Slow-wave plate: made of quartz, 329 mm in diameter φ, 7 mm in thickness

Planar antenna: 344 mm in diameter φ, 0.3 mm in thickness

Plasma transmitting plate: made of quartz, 362 mm in diameter φ, 31.3 mm (=½λ) in thickness, flat type, solid part in contact with planar antenna

Electric properties were set as follows.

Frequency: 2.45 GHz

Power density: 2.67 W/cm² (at 2750 W), 2.91 W/cm² (at 3000 W)

Input impedance: 50Ω (2.45 GHz)

Power reflection coefficient: 0.75 (2.45 GHz)

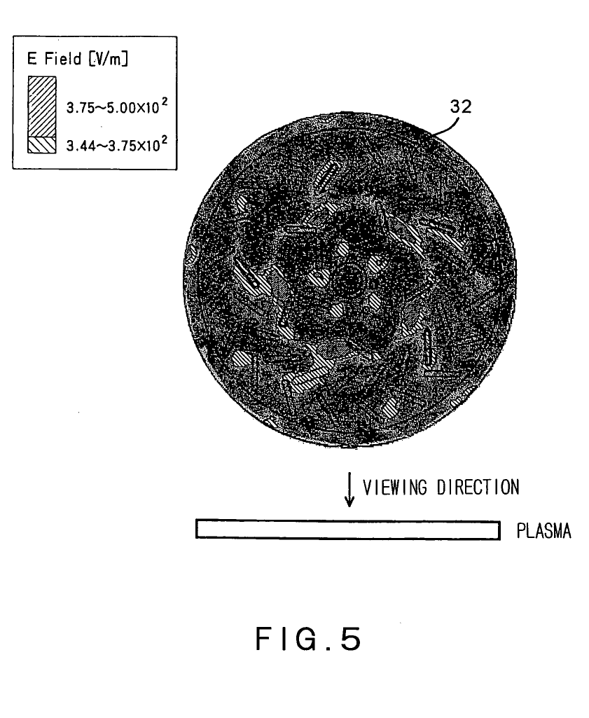

A simulation on an electric field distribution in the plasma transmitting plate was conducted under the above conditions. Analysis conditions were as follows. That is, as shown in FIG. 5, each of the plasma radiating holes (slots) had an elongated groove shape, and every two adjacent plasma radiating holes 32 were arranged to form an “L” shape. The L-shaped pairs (sets) of microwave radiating holes 32 were concentrically arranged to define a double circle. A plasma density was set at 1×10¹²/cm³. It was confirmed that, as shown in FIG. 5, an electric field distribution was relatively uniform, and that microwave power loss was small since a lot of parts exhibited an electric field strength as high as not less than 3×10² V/m, and even some parts exhibited an electric field strength as high as not less than 4×10² V/m.

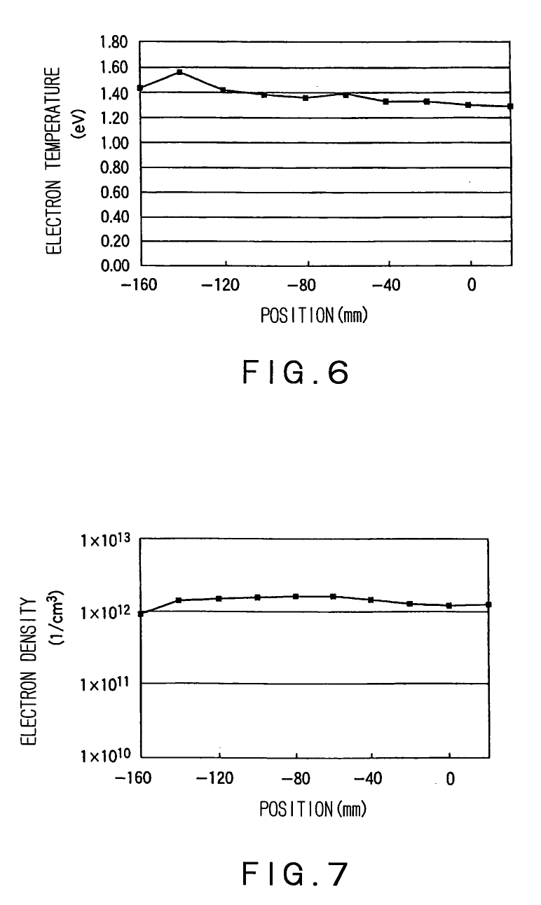

Next, a plasma was actually formed under the above conditions, and an electron temperature distribution and an electron density distribution were examined. Ar was used as a process gas. A pressure in the chamber was set at 1 Torr (133 Pa). A microwave power was set at 2750 W. FIG. 6 shows an electron temperature distribution, and FIG. 7 shows an electron density distribution.

As shown in FIG. 6, the electron temperature was not more than 1.6 eV, and the distribution variation was small. As shown in FIG. 7, the electron density was substantially not less than 1×10¹²/cm³, and the distribution variation was small. Namely, it was confirmed that a plasma of a low electron temperature and a high electron density was stably formed.

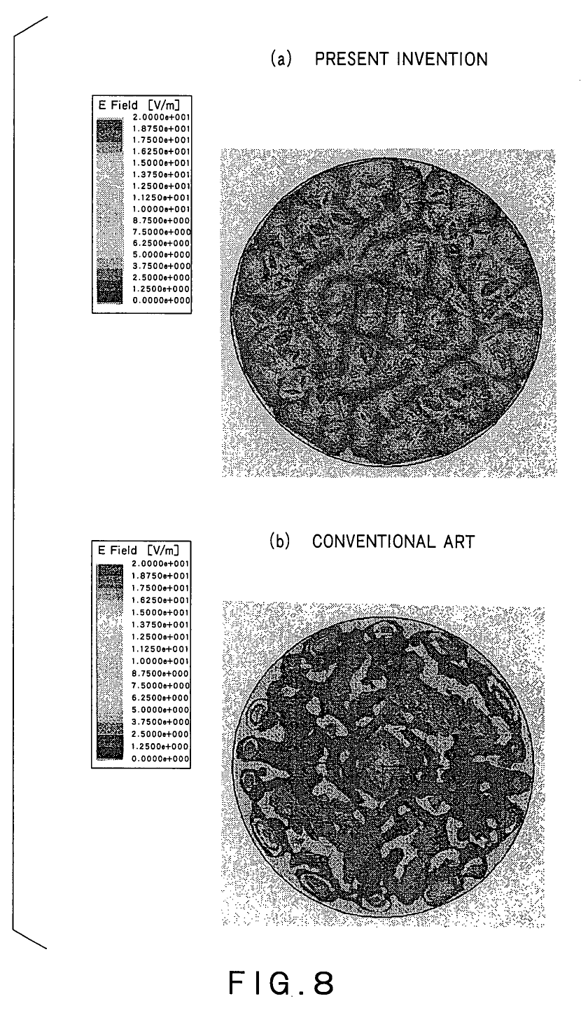

Next, a simulation was conducted for examining a microwave electric field strength in a microwave transmitting plate in each of the microwave plasma processing apparatus according to the present invention and a conventional microwave plasma processing apparatus having an air gap. The results are described below. In the simulation for the microwave plasma processing apparatus according to the present invention, the slow-wave plate 33, the planar antenna 1, the plasma transmitting plate 28, and the electric properties ere the same as those in the above experiment, and a plasma density was set at 1×10¹⁰/cm³. In the simulation for the conventional microwave plasma processing apparatus, a length (thickness) of the air gap was set to be 20 mm, in addition to the above conditions. FIGS. 8(a) and 8(b) show the results, respectively. As shown in FIG. 8(a), in the apparatus according to the present invention, there were found parts exhibiting a microwave electric field strength as high as not less than 1.75×10¹ V/m. On the other hand, as shown in FIG. 8(b), in the conventional apparatus, a lot of parts exhibited a microwave electric field strength as low as not more than 5 V/m. Namely, it was understood that, as compared with the conventional apparatus, the apparatus according to the present invention can significantly enhance the microwave electric field strength. Incidentally, it was revealed that there was no remarkable difference as to uniformity of the microwave electric field strength between the present invention and the conventional art.

A suitable semiconductor manufacturing apparatus based on the idea of the present invention as described above is, for example, an apparatus having the microwave transmitting plate 28 and the slow-wave plate 33 which are made of alumina (Al₂O₃), or an apparatus having these members made of quartz (SiO₂).

A plasma CVD apparatus can be raised as an example to which the apparatus having the microwave transmitting plate 28 and the slow-wave plate 33 made of alumina is suitably applied. When the microwave transmitting plate 28 and active species of a plasma react to each other to generate a gas containing an element constituting the microwave transmitting plate 28, there is a possibility that the gas is drawn into a film to be deposited on an object to be processed, to degrade a quality of the film. However, when the microwave transmitting plate 28 is made of alumina, since alumina is dense, a discharge amount of oxygen can be decreased by a factor of 10, as compared with quartz, for example. Alternatively, the microwave transmitting plate 28 and the slow-wave plate 33 may be formed by laminating an alumina material and a material different from alumina, so as to have a dielectric constant close to that of alumina. In this case, materials with a relative dielectric constant being within a range between 7.4 and 9.6 may be variously combined, such that a ratio between dielectric constants of these materials is within a range between 70% and 130% so that the resonance condition can be satisfied.

On the other hand, a plasma etching apparatus or a plasma surface modifying apparatus can be raised as an example to which the apparatus having the microwave transmitting plate 28 and the slow-wave plate 33 made of quartz is suitably applied. Under process conditions for etching and surface modification, the microwave transmitting plate 28 is spattered by ion impact. At this time, when an element constituting the microwave transmitting plate 28 is a metal, there is a possibility that an object to be processed is contaminated with the metal. Thus, for example, alumina cannot be used. In this case, if the microwave transmitting plate 28 is made of quartz, there is no fear of metal contamination. This is because, similarly to quartz containing an element Si as a principal component, the object to be processed is generally a silicon wafer or a glass substrate containing an element Si as a principal component.

In the apparatus having the microwave transmitting plate 28 and the slow-wave plate 33 which are made of quartz, when a radial interspace of the concentrically arranged microwave radiating holes 32 and a length from the center of the planar antenna 31 to the innermost microwave radiating hole 32 are set at Δr (see, FIG. 2), and the Δr is made identical to a wavelength of the microwave in the slow-wave plate, two turns of microwave radiating holes 32 are formed (arranged) for a microwave frequency of 2.45 GHz. The apparatus is intended or processing the prevailing 300 mm wafer, and thus a diameter of the planar antenna 31 is set to be substantially 300 mm. On the other hand, when the microwave transmitting plate 28 and the slow-wave plate 33 are made of alumina, three turns of microwave radiating holes 32 are formed (arranged). As compared with the apparatus having the two-turn arrangement, design and adjustment of the slots are significantly difficult in the apparatus having the three-turn arrangement. For example, in the three-turn apparatus, even when the number of the slots of the intermediate turn is increased, a plasma density directly therebelow cannot be necessarily elevated. To the contrary, density of a central plasma space is decreased while density of a circumferential plasma space is increased, or the inverse situation may occur. This is because the microwave radiated from the slots in the intermediate turn interfere with electromagnetic waves radiated from the slots in the inside turn and the outside turn. From this point of view, a quartz material in which two turns of microwave radiating holes 32 are formed is preferred as a material for forming the microwave transmitting plate 28 and the slow-wave plate 33. Alternatively, the microwave transmitting plate 28 and the slow-wave plate 33 may be formed by laminating quartz and another material different from quartz, so as to have a dielectric constant close to that of quartz. In this case, materials with a relative dielectric constant being within a range between 3.5 and 4.5 may be variously combined, such that a ratio between dielectric constants of these materials is within a range between 700% and 1300% so that the resonance condition can be satisfied. Similarly to the case in which the microwave transmitting plate 28 and the slow-wave plate 33 are made of quartz, two turns of microwave radiating holes 32 are formed (arranged) for a microwave frequency of 2.45 GHz.

Not limited to the above embodiment, the present invention can be modified in various ways. For example, as long as the constituent requirements of the present invention are satisfied, the structure of the processing apparatus is not limited to the above embodiment. Further, not limited to the oxidation process, the intended plasma process may be applied to various processes such as a film deposition process, an etching process, and so on. An object to be processed which is subjected to a plasma process is not limited to a semiconductor wafer, but may be another object such as a flat panel display substrate or the like.

The present invention as described above is suitable for a plasma process requiring a plasma of a low electron temperature and a high density, such as an oxidation process, a film-deposition process, an etching process, and so on, which are performed for manufacturing a semiconductor device.

1. A microwave plasma processing apparatus comprising:
a chamber in which an object to be processed is housed;
a process gas supply unit that supplies a process gas into the chamber;
a microwave generating source that generates a microwave for forming a plasma due to the process gas in the chamber;
a waveguide unit that guides the microwave generated by the microwave generating source toward the chamber;
a planar antenna made of a conductive material provided with a plurality of microwave radiating holes for radiating the microwave guided by the waveguide unit toward the chamber;
a microwave transmitting plate made of a dielectric material, the microwave transmitting plate serving as a top wall of the chamber and transmitting the microwave that has passed through the microwave radiating holes of the planar antenna; and
a slow-wave plate disposed on an opposite side of the planar antenna relative to the microwave transmitting plate, the slow-wave plate having a function of shortening a wavelength of the microwave that reaches the planar antenna;
wherein the planar antenna and the microwave transmitting plate are in contact with each other, with substantially no air therebetween,
the slow-wave plate and the microwave transmitting plate are made of the same material, and
an equivalent circuit formed by the slow-wave plate, the planar antenna, the microwave transmitting plate, and the plasma due to the process gas formed in the chamber satisfies a resonance condition.

2. A microwave plasma processing apparatus comprising:
a chamber in which an object to be processed is housed;
a process gas supply unit that supplies a process gas into the chamber;
a microwave generating source that generates a microwave for forming a plasma due to the process gas in the chamber;
a waveguide unit that guides the microwave generated by the microwave generating source toward the chamber;
a planar antenna made of a conductive material provided with a plurality of microwave radiating holes for radiating the microwave guided by the waveguide unit toward the chamber;
a microwave transmitting plate made of a dielectric material, the microwave transmitting plate serving as a top wall of the chamber and transmitting the microwave that has passed through the microwave radiating holes of the planar antenna; and
a slow-wave plate disposed on an opposite side of the planar antenna relative to the microwave transmitting plate, the slow-wave plate having a function of shortening a wavelength of the microwave that reaches the planar antenna;
wherein the planar antenna and the microwave transmitting plate are in contact with each other, with substantially no air therebetween,
the slow-wave plate and the microwave transmitting plate are made of materials with a ratio between dielectric constants of these materials being within a range between 70% and 130%, and
an equivalent circuit formed by the slow-wave plate, the planar antenna, the microwave transmitting plate, and the plasma due to the process gas formed in the chamber satisfies a resonance condition.

3. The microwave plasma processing apparatus according to claim 1 or 2, wherein
a thickness of the microwave transmitting plate is within a range between ½ and ¼ of the wavelength of the microwave to be introduced into the microwave transmitting plate, and
a microwave reflection ratio of the planar antenna is within a range between 0.4 and 0.8.

4. The microwave plasma processing apparatus according to claim 1 or 2, wherein
the waveguide unit includes a rectangular waveguide that propagates the microwave generated from the microwave generating source in a TE mode, a mode converter that converts the TE mode to a TEM mode, and a coaxial waveguide that propagates the microwave converted to the TEM mode toward the planar antenna.

5. The microwave plasma processing apparatus according to claim 1 or 2, wherein
each of the microwave radiating holes formed in the planar antenna has an elongated groove shape,
every adjacent two of the microwave radiating holes are arranged in directions crossing each other so as to form one microwave radiating hole pair, and
the plurality of microwave radiating hole pairs are concentrically arranged.

6. The microwave plasma processing apparatus according to claim 1 or 2, further comprising
a cover member that covers the slow-wave plate and the planar antenna.

7. The microwave plasma processing apparatus according to claim 6, wherein
the cover member is provided with a cooling medium passage, and
the slow-wave plate, the planar antenna, and the microwave transmitting plate are cooled by allowing a cooling medium to flow through the cooling medium passage.

8. The microwave plasma processing apparatus according to claim 1 or 2, wherein
a frequency of the microwave is 2.45 GHz,
a relative dielectric constant of the slow-wave plate and the microwave transmitting plate is between 3.5 and 4.5, and
the microwave radiating holes are arranged in double circles.

9. The microwave plasma processing apparatus according to claim 1 or 2, wherein
the slow-wave plate and the microwave transmitting plates are made of quartz, and
the microwave plasma processing apparatus is a plasma etching apparatus or a plasma surface modifying apparatus.

10. The microwave plasma processing apparatus according to claim 1 or 2, wherein
the slow-wave plate and the microwave transmitting plate are made of alumina, and
the microwave plasma processing apparatus is a plasma CVD apparatus.
